(19) United States
(12) Patent Application Publication
(10) Pub. No.: US 2025/0363428 A1
(43) Pub. Date: Nov. 27, 2025

(54) SYSTEMS AND METHODS FOR SHELF SPACE OPTIMIZATION

(71) Applicant: Kenvue Brands LLC, Summit, NJ (US)

(72) Inventors: Rahul Tyagi, Short Hills, NJ (US); Edward N. McGrath, Warrington, PA (US); Issac Mathew, Bengaluru (IN)

(21) Appl. No.: 19/084,925

(22) Filed: Mar. 20, 2025

Related U.S. Application Data
(60) Provisional application No. 63/651,105, filed on May 23, 2024.

(51) Int. Cl. G06Q 10/04; G06Q 10/087

(52) U.S. Cl. CPC G06Q 10/043; G06Q 10/087

(57) ABSTRACT

Systems and methos for generating a schematic for shelf space in a retail environment include acquiring fixture data for a fixture; acquiring item data for a plurality of items to be displayed on fixture; importing an existing planogram, the imported existing planogram comprising an existing location of each item of the plurality of items on the fixture; based on identified assortment rules, generating an updated planogram for the fixture, the generated updated planogram for the fixture including an optimized placement of the plurality of items on the fixture; and generating the schematic based on the generated updated planogram, the generated recommended schematic including a sequence of the plurality of items included in the generated updated planogram.

### CROSS-REFERENCE TO RELATED APPLICATION

This application claims the benefit of U.S. Provisional Application No. 63/651,105 filed May 23, 2024, the contents of which is incorporated herein by reference in its entirety.

### BACKGROUND

Organizing physical shelf space in a retail environment involves analysis of multiple factors, including products for sale, prices and sizes of those products, retail history of the physical location, seasonality, packaging of the products, available shelf space, and so forth. In particular, organizing the physical shelf space requires the analysis of these factors in order to best identify the locations of each physical products on the physical shelf in order to maximize sales. However, current solutions fail to take each of these variables into account and, even if they do attempt to account for each variable, fail to generate an entire display that takes into account each of these factors.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various implementations of the present disclosure described herein are directed to systems and methods that generate a schematic for shelf space in a retail environment. In some examples, a computer-implemented method includes acquiring fixture data for a fixture; acquiring item data for a plurality of items to be displayed on fixture; importing an existing planogram, the imported existing planogram comprising an existing location of each item of the plurality of items on the fixture; based on identified assortment rules, generating an updated planogram for the fixture, the generated updated planogram for the fixture including an optimized placement of the plurality of items on the fixture; and generating a recommended schematic for a retail environment based on the generated updated planogram.

In some examples, a system includes a memory; and a processor coupled to the memory, a pre-processor, implemented on the processor, configured to acquire fixture data for a fixture, acquire item data for a plurality of items to be displayed on fixture, and import an existing planogram, the imported existing planogram comprising an existing location of each item of the plurality of items on the fixture; a planogram generator, implemented on the processor, configured to, based on identified assortment rules, generate an updated planogram for the fixture, the generated updated planogram for the fixture including an optimized placement of the plurality of items on the fixture; and a schematic generator, implemented on the processor, configured to generate a recommended schematic for a retail environment based on the generated updated planogram.

In some examples, one or more non-transitory computer-readable medium storing instructions that, when executed by a processor, cause the processor to acquire fixture data for a fixture, acquire item data for a plurality of items to be displayed on fixture, import an existing planogram, the imported existing planogram comprising an existing location of each item of the plurality of items on the fixture; derive an existing customer decision tree (CDT) from the imported planogram; identify the assortment rules based on the derived CDT; based on the identified assortment rules, generate an updated planogram for the fixture, the generated updated planogram for the fixture including an optimized placement of the plurality of items on the fixture; and generate a recommended schematic for a retail environment based on the generated updated planogram, the generated recommended schematic including a sequence of the plurality of items included in the generated updated planogram.

### BRIEF DESCRIPTION OF THE DRAWINGS

The present description will be better understood from the following detailed description read in light of the accompanying drawings, wherein:

FIG. 1 illustrates an example system for optimizing shelf space according to an example;

FIG. 2 illustrates an example planogram according to an example;

FIG. 3 illustrates an example computer-implemented method of optimizing shelf space according to an example;

FIG. 4 illustrates an example computer-implemented method of reverse engineering existing merchandise rules according to an example;

FIG. 5 illustrates an example computer-implemented method of generating a recommendation of an example planogram according to an example;

FIG. 6 illustrates an example computer-implemented method of generating a recommendation of an example planogram according to an example;

FIG. 7 illustrates an example computer-implemented method of generating a recommendation of an example planogram according to an example;

FIG. 8 illustrates an example computer-implemented method of generating a recommendation of an example planogram according to an example; and

FIG. 9 is a block diagram illustrating an example computing environment suitable for implementing one or more of the various examples disclosed herein.

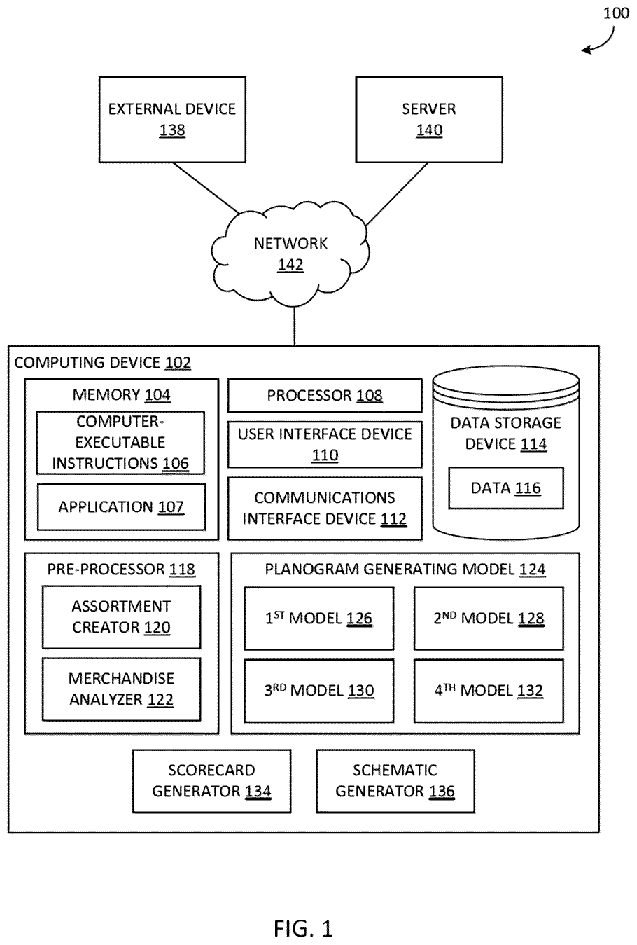

Corresponding reference characters indicate corresponding parts throughout the drawings. In FIGS. 1 to 9, the systems are illustrated as schematic drawings. The drawings may not be to scale.

### DETAILED DESCRIPTION

The various implementations and examples will be described in detail with reference to the accompanying drawings. Wherever possible, the same reference numbers will be used throughout the drawings to refer to the same or like parts. References made throughout this disclosure relating to specific examples and implementations are provided solely for illustrative purposes but, unless indicated to the contrary, are not meant to limit all examples.

As described herein, organizing physical shelf space in a retail environment presents significant challenges due to the required analysis of multiple factors including details associated with each product for sale such as the prices, sizes, features, brands, and sales history of those products, retail history of the physical location, seasonality, packaging of the products, available shelf space, consumer buying behavior at the physical location, and so forth. Current solutions, including manual organization, which is time-consuming, inefficient, and prone to error, and electronic organization, which is a one-size-fits-all approach that fails to consider many of the factors that have a direct impact on sales volume, fails to effectively organize physical shelf space in a way that balances sales, consumer shoppability (including merchant rules and aesthetics), and inventory and labor costs, including days of supply (DOS) variance and pack out achievement. As referenced herein, the term packout refers to an ideal number of case pack units that should be placed on a fixture, or shelf. In other words, current solutions fail to resolve the inherent challenges associated with maximizing the likelihood of sales for items that consumers are most likely to be searching for, while also minimizing the amount of time required for a sales associate to arrange the physical shelf space from an original schematic to an improved schematic that will address the retailer's revenue goals.

Various examples of the present disclosure recognize and take into account these challenges and provide systems and methods for generating an optimized planogram that optimizes shelf space based on an existing shelf configuration and additional factors associated with the physical location and details associated with the products that are to be placed on the shelf. The method includes capturing details regarding the items to be placed on a fixture, i.e., a physical shelf, capturing details regarding the fixture, importing an existing shelf space schematic including the fixture and the items placed on the fixture, generating assortment rules for the fixture by inferring a consumer decision tree (CDT) that informs how a consumer makes a purchasing decision for the item or items on the fixture, and generating a planogram for the fixture based on the generated assortment rules. Once a planogram is generated for each fixture, i.e., physical shelf, a full schematic is generated that includes each fixture and a recommendation, including the generated full schematic, is generated.

The systems and methods for generating an optimized planogram operate in an unconventional manner by implementing multiple artificial intelligence (AI) or machine learning (ML) models that operate in conjunction to identify an optimal arrangement of products on fixtures, including the relationship between different fixtures in a single schematic, in order to ultimately generate a full schematic of products placed on fixtures. For example, the system includes inferring a Consumer Decision Tree (CDT) based on an existing fixture schematic to gain an understanding of how consumers make purchasing decisions at the particular retail location or in a particular type of retail location. The inferred CDT includes assortment rules for the fixture and items placed on the fixture. Based on the inferred CDT, a planogram is created for the fixture using one or more AI models that determine an optimal arrangement of items on the fixture that maintains compliance with the assortment rules.

Accordingly, the systems and methods for generating an optimized planogram provide a technical solution to a technical problem by reducing the burden of user input or otherwise user interaction from traditional processes, where a retail associate may open an application, drop and drag different example items onto an example fixture, and generate an example planogram that is typically not based on reliable historical data. The systems and methods described herein further reduce the consumption of computing resources by collecting and storing item and fixture data, as well as schematic data for a particular type of retail environment, such that similar retail environments, e.g., similarly sized retail stores in similar areas with similar customer bases, may reuse similar schematics for a display area rather than each retail store generating a separate planogram.

In some examples, the systems and methods described herein generates an optimized planogram that balances four mutually conflicting objectives, which are to maximize sales by maximizing assortment on the fixture, minimize lost sales by maximizing the average days of supply on the fixture, i.e., the number of days of sales that the units on the fixture can support, minimize store labor costs by maximizing the number of items that meet the packout value as described herein, and maximize aesthetics and shoppability by creating rectangular blocks and penalizing the deviations from the rectangular shape for a block. The penalty mechanism penalizes violations of the aforementioned guidelines using TDOS (Target Days of Supply) and TCP (Target Case Packs). The multi-objective function executes to maximize sales while minimizing sum total of penalties. In various examples, each of the four mutually conflicting objectives described herein may be adequately weighted to give preference to one or more objectives over others.

FIG. 1 illustrates an example system for optimizing shelf space according to an example. The system 100 illustrated in FIG. 1 is provided for illustration only. Other examples of the system 100 can be used without departing from the scope of the present disclosure. In some examples, the system 100 generates a recommendation for optimizing shelf space as described herein.

The system 100 includes a computing device 102, an external device 138, a server 140, and a network 142. The computing device 102 represents any device executing computer-executable instructions 106 (e.g., as application programs, operating system functionality, or both) to implement the operations and functionality associated with the computing device 102. The computing device 102 in some examples includes a mobile computing device or any other portable device. A mobile computing device includes, for example but without limitation, a mobile telephone, laptop, tablet, computing pad, netbook, gaming device, and/or portable media player. The computing device 102 can also include less-portable devices such as servers, desktop personal computers, kiosks, or tabletop devices. Additionally, the computing device 102 can represent a group of processing units or other computing devices.

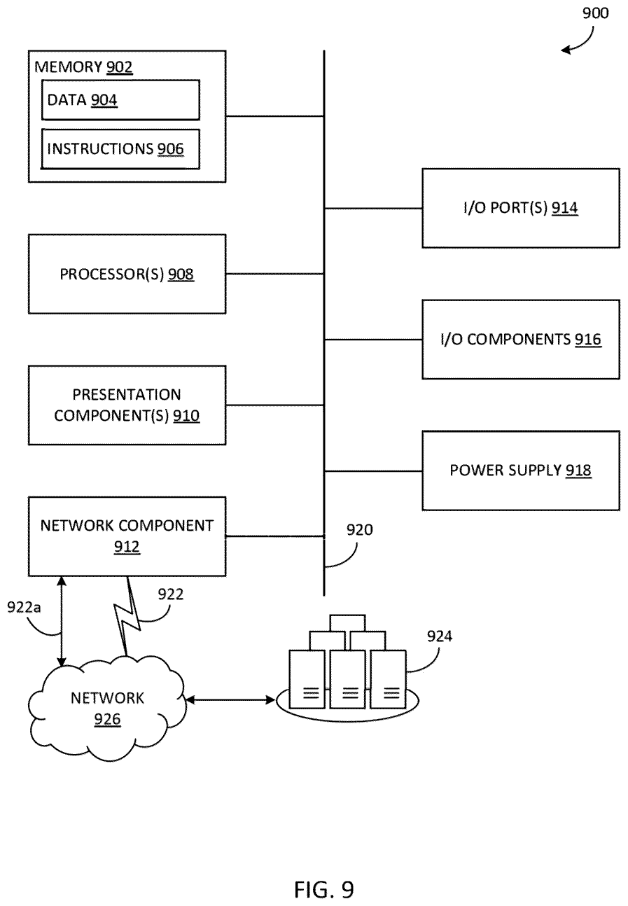

In some examples, the computing device 102 includes at least one processor 108, a memory 104 that includes the computer-executable instructions 106, and a user interface device 110. The processor 108 includes any quantity of processing units and is programmed to execute the computer-executable instructions 106. The computer-executable instructions 106 are performed by the processor 108, performed by multiple processors within the computing device 102, or performed by a processor external to the computing device 102. In some examples, the processor 108 is programmed to execute computer-executable instructions 106 such as those illustrated in the figures described herein, such as FIG. 9. In various examples, the processor 108 is configured to execute computer-executable instructions of one or more of the pre-processor 118, planogram generating model 124, scorecard generator 134, and schematic generator 136 as described herein.

The memory 104 includes any quantity of media associated with or accessible by the computing device 102. In some examples, the memory 104 is internal to the computing device 102. In other examples, the memory 104 is external to the computing device 102 or both internal and external to the computing device 102. For example, the memory 104 can include both a memory component internal to the computing device 102 and a memory component external to the computing device 102, such as the server 136. The memory 104 stores data, such as one or more applications 107. The applications 107, when executed by the processor 108, operate to perform various functions on the computing device 102. The applications 107 can communicate with counterpart applications or services, such as web services accessible via the network 138. In an example, the applications 107 represent server-side services of an application executing in a cloud, such as a cloud server 136. In some examples, the application 107 is an application for generating a recommendation for a planogram that optimizes shelf space in a retail environment.

The user interface device 110 includes a graphics card for displaying data to a user and receiving data from the user. The user interface device 110 can also include computer-executable instructions, for example a driver, for operating the graphics card. Further, the user interface device 110 can include a display, for example a touch screen display or natural user interface, and/or computer-executable instructions, for example a driver, for operating the display. The user interface device 110 can also include one or more of the following to provide data to the user or receive data from the user: speakers, a sound card, a camera, a microphone, a vibration motor, one or more accelerometers, a BLUETOOTH® communication module, global positioning system (GPS) hardware, and a photoreceptive light sensor. In a non-limiting example, the user inputs commands or manipulates data by moving the computing device 102 in one or more ways.

The computing device 102 further includes a communications interface device 112. The communications interface device 112 includes a network interface card and/or computer-executable instructions, such as a driver, for operating the network interface card. Communication between the computing device 102 and other devices, such as but not limited to the user device 136, can occur using any protocol or mechanism over any wired or wireless connection.

The computing device 102 further includes a data storage device 114 for storing data 116. The data 116 includes, but is not limited to, template planogram data, item data, fixture data, assortment data, and merchandising rules. Item data includes at least one of item master data, item performance data at a store level, and item performance data at a cluster or chain level. Item master data may include an item code, item attributes such as Brand-Sub-Category-Size, item dimensions, item units per case, an item squish factor, whether the item is stackable, item CDT data, and days of supply (DoS) data. The item performance data may include, at the store level, item unit sales per store per week, item dollar sales per store per week, and item profit per store week. The item performance data may include, at the chain or cluster level, at least one of item unit sales per store per week, item dollar sales per store per week, and item profit per store week. The fixture data includes at least one of a section name, a section length, a section least count, a jump or break sub-section in the section, a number of shelves in the section, shelf numbers, a depth of each shelf, a height of each shelf, an airgap by the shelf, and an overhang of the shelf. The template planogram data includes, for each item, information including the shelf number, orientation number, number of facings, and, if applicable, sequence number on the shelf. Assortment includes at least one of master assortment data, assortment ranking criteria, and assortment rules. Master assortment data includes a store assortment and a cluster assortment. Assortment ranking criteria includes unit sales, dollar sales, margin, or a weighted combination of the unit sales, dollar sales, and margin. The assortment rules include coverage, in units per dollar, by a CDT node, adjacency of one item to another, complementarity data such as if item A is present then item B should be present, and exclusivity data such as if item A is present then item B should not be present. The merchandising rules include at least one of blocking data, sequencing data, whether the merchandise is presented as snaking or broken, and ribboning data, referring to a shelf sequence number combination by items. Blocking data includes a block sequence, block type, and block adjacencies, while sequencing data includes an attribute used for sequencing and an attribute value flow for sequencing such as ascending, descending, or qualitative.

The pre-processor 118 is an example of a specialized computing unit executed on the processor 108 that performs the specialized function of pre-processing for the planogram generating model 124. The pre-processor 118 includes an assortment creator 120 and a merchandise analyzer 122. The assortment creator 120 normalizes assortment performance metrics from the assortment data using the assortment ranking criteria and, based on the normalized scores of the assortment performance metrics, generates a ranked assortment list of items. Thus, the assortment creator 120 defines the attributes and rules to be used to generate an updated planogram for a fixture or fixtures. This includes the item or items eligible to be included on the fixture, what items are mandatory for inclusion with other items, what items are exclusive relative to other items, and so forth.

The merchandise analyzer 122 imports an existing planogram and derives a CDT for the imported planogram. The derived CDT is a decision tree by which a consumer makes a purchasing decision to select a particular item or items instead of a potential replacement item. For example, the derived CDT includes assortment rules for why a consumer selects a particular shampoo of a particular size instead of a similar shampoo of the particular size, a particular lotion of a particular size instead of a similar lotion, or any other suitable product. For example, a consumer shopping for sunscreen a family of four may prefer a sunscreen with a greater volume over a lesser volume, at a specific sun protection factor (SPF), and including (or excluding) particular ingredients. In some examples, items are arranged in blocks of items. For example, a block of items may include all shampoo items to be sold in the planogram, all sunscreen items to be sold in the planogram, and so forth. In another example, a block of shampoo items may be further subdivided into sub-blocks that each include a particular brand's shampoo items, while a block of sunscreen items may be further subdivided into sub-blocks that each include a particular brand's sunscreen items, and so forth. In combination with assortment rules for a planogram, such as having items, or blocks of items, sorted by volume on the fixture such that the volumes of the items descend in size from left to right on the fixture, having items, or blocks of items, sorted by volume on different fixtures such that the volumes of the items descend in size from a top fixture to a bottom fixture, sequencing rules for the order in which items, or blocks of items, are provided on the fixture, and so forth, the merchandise analyzer 122 derives the CDT for the particular imported planogram.

Following deriving the CDT for the particular imported planogram, for each item in the imported planogram, the merchandise analyzer 122 identifies the block in which the item is included and which fixture each block of items is situated on, determines the flow of the various blocks along the fixture or fixtures, and generates an item-block-fixture matrix that identifies, for each item, which block the item is included in and which fixture, or shelf, the block is placed on. For example, a particular shampoo item that is identified as the third item in a second block on a fourth fixture may be identified within the item-block-fixture matrix as 3:2:4.

The merchandise analyzer 122 then calculates an item facing capacity value for the fixture. The item facing capacity value is a value that represents the capacity of item facings for a particular fixture. As noted above, item data for each item includes facings data. The facings data includes a number of facings on an item, such as one, two, or four, and a length of each facing. Some items may be advantageously presented on a fixture with a front facing, which other items may be advantageously presented on the fixture with a side facing. In other examples, the facings data includes only a single facing, e.g., a front facing, with a length for the front facing.

The planogram generating model 124 is an example of a specialized computing unit executed on the processor 108 that performs the specialized function of generating a planogram, or planograms, including items on fixtures, based on the results of the pre-processor 118, including the assortment creator 120 and the merchandise analyzer 122. The generated planogram or planograms may then be used by a schematic generator 136 to generate a full schematic of item placement for a retail environment, as described in greater detail below. The planogram generating model 124 includes a first model 126, a second model 128, a third model 130, and a fourth model 132. In some examples, each of the first model 126, second model 128, third model 130, and fourth model 132 are implemented in conjunction to generate a planogram for one or more fixtures. In other examples, only one of the first model 126, second model 128, third model 130, and fourth model 132 is implemented to generate a planogram for one or more fixtures. In yet another example, a combination of at least two of the first model 126, second model 128, third model 130, and fourth model 132 are used in conjunction to generate a planogram for one or more fixtures.

The planogram generating model 124 is trained based on historical data including, but not limited to, historical item position performance for each respective item along with the restraints in place at the time the performance data is captured. The historical item position performance data is obtained from a retailer at which a particular item, or set of items, is sold and stored in the data storage device 114 as an example of the data 116. The historical item position performance further includes controls for merchandising rules that are related to packout constraints, expected sales, and the trade-off between incremental items and short-term stock outs. For example, a particular item subject to particular packout restraints, expected and realized sales, and data regarding the weighting of incremental item vs. short-term stock out for the particular time period and physical location is used to the train the planogram generating model 124 for the item. As additional data is added for additional items, constraints, time periods, and locations, the planogram generating model 124 is finetuned and optimized to identify optimal locations on a fixture for different items based on varying constraints.

As described in greater detail below, each of the first model 126, second model 128, third model 130, and fourth model 132 are various examples of AI models that, when implemented by the planogram generating model 124, execute in different ways to generate the planogram or planograms. The first model 126 generates an updated planogram by adding items onto a fixture without changing the location of existing items in the imported planogram, and instead identifying items that are highly ranked by the merchandise analyzer, but not included on the fixture, and determining optimal placement of the identified items on the fixture in the updated planogram. The second model 128 generates an updated planogram by adding items to the fixture in the imported planogram. The second model 128 creates space on the fixture where an eligible item may fit. Some items may be rearranged or moved on the fixture, or even between fixtures in the planogram, but blocks on the fixture are not broken up. In other words, existing blocks of items are not separated by the second model 128. In some examples, the second model 128 may be implemented where item-fixture eligibility varies due to different available heights on a fixture, different heights of the products, or both.

The third model 130 generates an updated planogram by reducing the facings of each item in the imported planogram to one, such that each item only has a single facing on the fixture, then implements the first model 126, and then implements the second model 128. Various iterations of the third model 130 either maximize the use of fixture space at the potential cost of reducing lost sales, or reduce lost sales over more efficient use of the fixture space. The fourth model 132 takes yet another approach and instead of updating the imported planogram, generates an entirely new planogram based on the generated assortment rules and derived CDT by the merchandise analyzer 122.

The scorecard generator 134 is an example of a specialized computing unit executed on the processor 108 that generates a scorecard with information related to the generated planogram by the planogram generating model 124. For example, the generated scorecard includes a rating, or grade, of various aspects of the generated planogram includes anticipated sales of the generated planogram, anticipated lost sales of the planogram, an anticipated labor cost of preparing the retail environment in accordance with the generated planogram, anticipated excess inventory based on the generated planogram, synthetic calculated penalties for violations of business rules, and in some examples a blocking penalty that measures a trade-off introduced by a focus on an aesthetically good looking planogram, increased sales, and lower inventory and labor costs. In some examples, the scorecard generator 134 generates the scorecard based on an analysis of the generated planogram. In other examples, the scorecard generator 134 generates the scorecard based on feedback received from a user, such as feedback received directly via the user interface device 110 or via the external device 138 that is then transmitted to the computing device 102 via the network 142.

In some examples, a scorecard is generated for each fixture of the generated planogram prior to a sequence of items being generated for the next fixture. In other words, when a planogram is generated for the first fixture, a scorecard is generated, and then, upon the scorecard indicating the generated planogram for the first fixture is sufficient, the planogram generating model 124 proceeds to a next fixture and generates a planogram for the next fixture. In other examples, a full planogram is generated for each fixture and then a scorecard is generated for the entire planogram, including each fixture in the imported planogram.

The schematic generator 136 is an example of a specialized computing unit executed on the processor 108 that generates a schematic for a retail environment based on one or more generated planograms. For example, the schematic generator 136 generates an output of the form item, including fixture number, sequence number, orientation, capping/stacking units, and so forth, to build a schematic that can be used to apply the planogram to a physical retail environment.

The external device 138 is another example of a computing device, separate from and external of the computing device 102. In some examples, the external device 138 includes a mobile computing device or any other portable device. A mobile computing device includes, for example but without limitation, a mobile telephone, laptop, tablet, computing pad, netbook, gaming device, and/or portable media player. The external device 138 can also include less-portable devices such as servers, desktop personal computers, kiosks, or tabletop devices. Additionally, the external device 138 can represent a group of processing units or other computing devices. The server 136, in some examples, is an example of an external storage device, remote data storage device, a data storage in a remote data center, or a cloud storage.

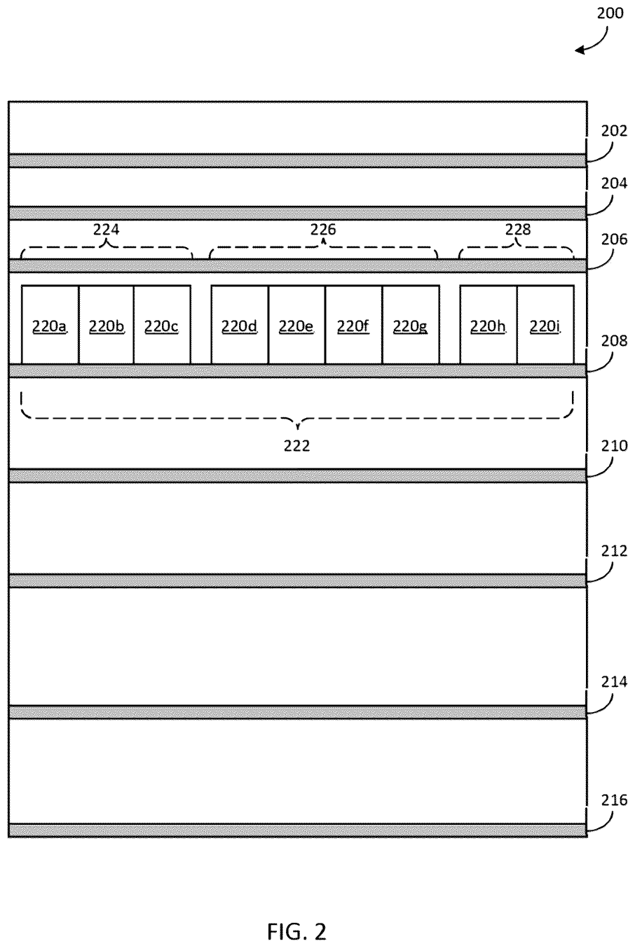

FIG. 2 illustrates an example planogram according to an example. The example planogram 200 illustrated in FIG. 2 is presented for illustration only and should not be construed as limiting. Various examples are possible.

The planogram 200 includes a plurality of fixtures, or shelves. For example, the planogram 200 includes a first fixture 202, a second fixture 204, a third fixture 206, a fourth fixture 208, a fifth fixture 210, a sixth fixture 212, a seventh fixture 214, and an eighth fixture 216. The planogram 200 further includes a plurality of items 220 arranged on the fourth fixture 208. As illustrated in FIG. 2, the plurality of items 220 includes a first item 220a, a second item 220b, a third item 220c, a fourth item 220d, a fifth item 220e, a sixth item 220f, a seventh item 220g, an eighth item 220h, and a ninth item 220i. However, the plurality of items 220 illustrated in FIG. 2 are presented for illustration only and various examples are possible. It should be understood that the plurality of items 220, and arrangement of the plurality of items 220, may depart from the configuration illustrated in FIG. 2 without departing from the scope of the present disclosure. The plurality of items 220 are arranged in a sequence 222, which indicates a placement of each item 220 within the sequence 222.

The plurality of items 220 are further arranged in blocks. For example, a first block 224 includes the first item 220a, second item 220b, and third item 220c. A second block 226 includes the fourth item 220d, fifth item 220e, sixth item 220f, and seventh item 200g. A third block 228 includes the eighth item 220h and ninth item 220i. However, the blocks 224-228 illustrated in FIG. 2 are presented for illustration only and various examples are possible. It should be understood that the number of blocks on a fixture, sequence of blocks on a fixture, and number of items contained within a block may vary from the configuration illustrated in FIG. 2 without departing from the scope of the present disclosure.

In some examples, the size of the space available over a particular fixture differs from fixture to fixture. For example, as shown in FIG. 2, the space available on the eighth fixture 216 is greater than the space available on the second fixture 204. This provides space for larger items to be placed on the eighth fixture 216, as those items may have a height that is greater than the height from the second fixture 204 to the bottom of the first fixture 202, and therefore would not be able to fit on the second fixture 204. The planogram generating model 124 takes such data into account, as part of the data 116, and does not arrange items onto a particular fixture in which the items would not fit.

Although FIG. 2 illustrates items 220 on a single fixture, the fourth fixture 208, it should be understood that this is for ease of illustration only and should not be construed as limiting. In some examples, items 220 are placed on more than one fixture in the planogram 200. Further, a retail environment may include multiple of planograms 200. For example, an aisle in a retail environment may include multiple planograms 200 on each side of the aisle. The items 220 placed on the planogram 200 for sale include any number of items, including consumer health products, grocery items, electronics, household items, toys, office supplies, sporting goods, or any other suitable items for sale.

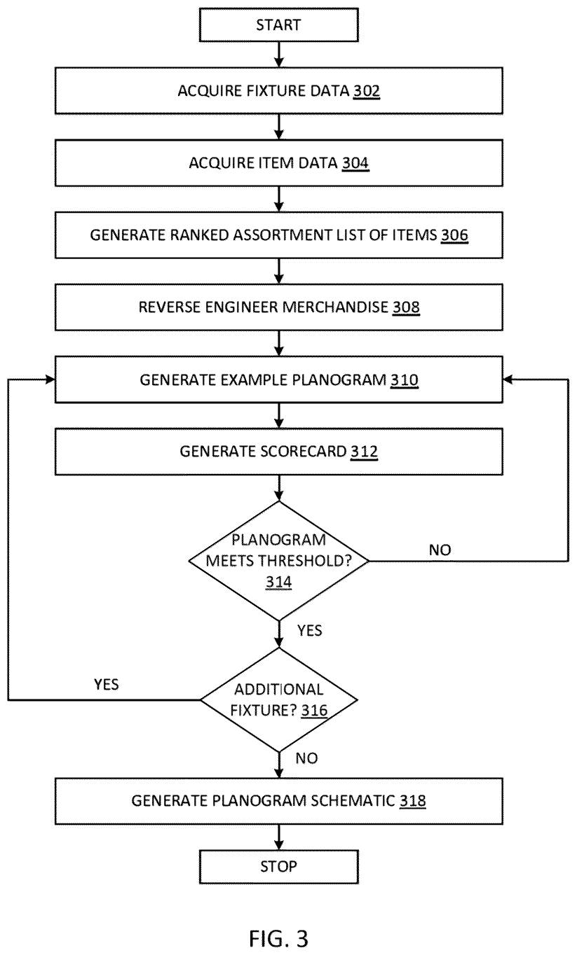

FIG. 3 illustrates an example computer-implemented method of optimizing shelf space according to an example. The computer-implemented method 300 is presented for illustration only and should not be construed as limiting. Other examples of the computer-implemented method 300 can be used without departing from the scope of the present disclosure. The computer-implemented method 300 can be implemented by one or more electronic devices described herein, such as the computing device 102.

The computer-implemented method 300 begins by the assortment creator 120 acquiring fixture data in operation 302 and item data in operation 304. In some examples, operations 302 and 304 are performed in sequence, with operation 304 being performed after operation 302 or operation 302 being performed after operation 304. In other examples, operations 302 and 304 are performed simultaneously. As described herein, the fixture data includes at least one of a section name, a section length, a section least count, a jump or break sub-section in the section, a number of fixtures in the section, shelf numbers, a depth of each shelf, a height of each shelf, an airgap by the shelf, and an overhang of the shelf. The item data includes at least one of item master data, item performance data at a store level, and item performance data at a cluster or chain level. Item master data includes an item code, item dimensions, item units per case, an item squish factor, whether the item is stackable, whether the item may be placed on a shelf cap and if so, how many may be placed on the cap, and item CDT data. The item performance data includes, at the store level, at least one of item unit sales per store per week, item dollar sales per store per week, and item profit per store week. The item performance data includes, at the chain or cluster level, at least one of item unit sales per store per week, item dollar sales per store per week, and item profit per store week.

In operation 306, the assortment creator 120 normalizes assortment performance metrics from the assortment data using the assortment ranking criteria and, based on the normalized scores of the assortment performance metrics, generates a ranked assortment list of items. For example, the assortment creator 120 defines the attributes and rules to be used to generate an updated planogram for a fixture or fixtures, including the item or items eligible to be included on the fixture, what items are mandatory for inclusion with other items, what items are exclusive relative to other items, and so forth.

In operation 308, the merchandise analyzer 122 imports an existing planogram and reverse engineers merchandise in the imported planogram by deriving a CDT for the imported planogram. For example, the merchandise analyzer 122 identifies each fixture on the imported planogram, identifies a block on each existing fixture of the imported planogram, creates a block membership table form a highest CDT level to a lowest CDT level, executes block sequencing logic in order to determine the existing sequencing rules for the blocks, and identifies item capacity, pack-out, and days of supply by facings by each fixture according to the orientation of the items by stacking and capping the items. The pack-out refers to a number of cartons, or cases, or partial cartons of the item on the fixture. Ideally, a whole number of cartons is placed on the fixture to maintain all the inventory of the item on the fixture, preventing a human stocker from putting only a partial case of items back to the stock or storage room. However, this is balanced with other sequencing rules, CDT levels, and so forth. To identify a block on an existing fixture of the existing planogram, the merchandise analyzer 122 identifies the first fixture on the planogram and then identifies the first sequence on the first fixture. The merchandise analyzer 122 determines, fixture by fixture and left to right for each fixture, a value of attributes associated with the products on the fixture in that sequence. For each fixture, the frequency of change of attribute values is then tabulated. The attribute value having a greatest change is assigned to the lowest level of the CDT. The product attribute with the next highest change frequency is assigned one level higher in the CDT and so on, until the attribute value having the least change frequency is reached. This product attribute is assigned to the top level of the CDT. Thus, the CDT is also a representation of how the blocks are laid out on each fixture and each higher level of the CDT acts as a parent block to all blocks at that level. As referenced herein, the cutoff is a threshold in a value for each sequence that determines an allowable amount of non-matching sequential item attributes. The merchandise analyzer 122 then repeats this process for a second fixture, third fixture, and so forth until the process has been repeated for each fixture.

The merchandise analyzer 122 then identifies which block each fixture is situated on by creating the block membership table. The block membership table is created from the highest level of the CDT to the lowest. To determine which fixture a block belongs to, i.e., block-shelf membership, the merchandise analyzer 122 finds, for each block starting with the first fixture, which fixture the block is on and captures highest to lowest fixture for the block. To determine which block an item belongs to, i.e., block-item membership, the merchandise analyzer 122 identifies member items for each fixture beginning with the highest level of the CDT to the lowest. To determine whether a particular item is eligible to be placed on a particular fixture, i.e., item-fixture membership, the merchandise analyzer 122 finds a lowest level CDT node block of which the item is a part of based on the item-block membership. The merchandise analyzer 122 determines whether the node's block has more than one item and if so, identifies fixtures for the block based on the identification of block shelf membership. Each fixture is added to the item's fixture eligibility. If no, the item is not eligible to be moved to another fixture. Where the item is the only item at that particular node, the merchandise analyzer 122 identifies the block-fixture membership of other children of the same parent. The entire range of block-shelf membership of all children becomes eligible shelves for this item, providing greater flexibility in placing the item or items on the fixtures of the planogram. As referenced herein, a node is the attribution combination that defines the merchandising block. The attribute combination includes a parent and child, where the parent-child combination refers to the order of the blocks. The parent-child combination is derived from the frequency attributes change across the fixture. For example, a sub-brand+form could describe the node, where the sub-brand is a parent of form because the sub-brand varies less frequently than the form. In this example, a brand having different types of products, such as wipes, cleansers, creams, and so forth, would be organized together under the whole sub brand block.

To create the block sequencing logic, the merchandise analyzer 122 performs the following process from the highest level of the CDT to the lowest. In other words, the highest level CDT loop run will be for all items on a shelf but subsequent runs where we are getting to child branches of CDT, the loop will run within the parent node and not across all nodes at that level. A first step of nesting run from a first fixture to the final fixture, while a second step of nesting determines a block boundary by, for each item at a sequence number, identifying the items in the sequence after which there is a change in value. The second step of nesting further captures the block sequence on each fixture for each block, from the highest level of the derived CDT on down, and for each fixture.

The merchandise analyzer 122 identifies the item capacity, pack-out, and days of supply by facings by each fixture for each item. For each fixture on which an item is eligible to be placed, for each orientation a stackable capacity, cappable capacity, case pack, and days of supply (DOS) is calculated. A stackable item capacity is determined based on multiplying a round down of the fixture and item height by the round down of the fixture and item width. Item capacity for a cap is determined in a similar manner with the addition of adding a round down value of the fixture and item depth. An example of rounding down would be a fixture or item depth of 1.3 inches being rounded down to 1, in order to determine how many items stacked on top of each other can fit in the space. For example, for a fixture that is ten inches long and an item is four inches wide, ten divided four equals 2.5, and the rounded down value is 2, indicating that two products may be stacked in the ten inches of space. A case pack, of items per facing, is calculated by dividing the capacity, either stackable or cappable, by the case pack value. A DoS, of items per facing, is calculated by dividing the capacity by the average rate of daily unit sales.

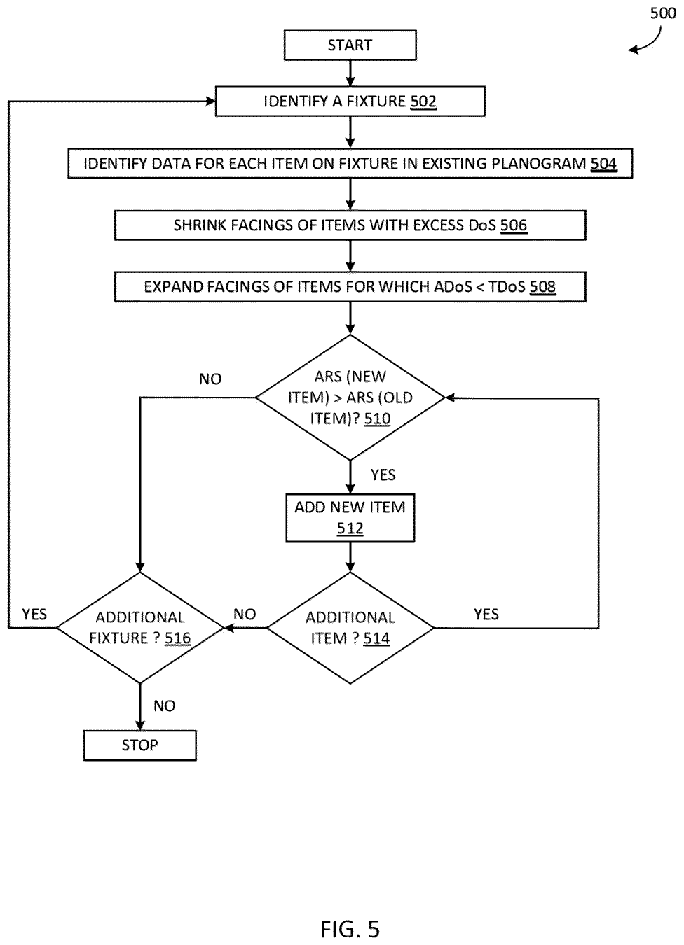

In operation 310, the planogram generating model 124 generates an updated planogram that includes specific items on the fixture based on the results generated by the pre-processor 118, including the assortment creator 120 and the merchandise analyzer 122. In various examples, the planogram generating model 124 generates the updated planogram using one or more of the first model 126, second model 128, third model 130, or fourth model 132, described in greater detail below with regards to FIGS. 5-8.

In operation 312, the scorecard generator 134 generates a scorecard with information related to the generated fixture of the planogram. For example, the generated scorecard includes a rating, or grade, of various aspects of the generated planogram includes anticipated sales of the generated planogram, anticipated lost sales of the planogram, an anticipated labor cost of preparing the retail environment in accordance with the generated planogram, anticipated excess inventory based on the generated planogram, synthetic calculated penalties for violations of business rules, and in some examples a blocking penalty that measures a trade-off introduced by increasing the assortment of items on the planogram to the corresponding added sales versus reducing lost sales. In some examples, the scorecard generator 134 generates the scorecard based on an analysis of the generated planogram. In other examples, the scorecard generator 134 generates the scorecard based on feedback received from a user, such as feedback received directly via the user interface device 110 or via the external device 138 that is then transmitted to the computing device 102 via the network 142.

In operation 314, the scorecard generator 134 determines whether the score on the generated scorecard meets a score threshold indicating that the generated planogram is sufficient for implementation. for example, the scorecard may include a numerical score on a scale of one to ten or one to one hundred, where the threshold for sufficiency is eight or eighty, respectively. Where the score meets or exceeds the score threshold, the generated planogram is accepted and the computer-implemented method 300 proceeds to operation 316. Where the score does not meet or exceed the score threshold, the generated planogram is not accepted and the computer-implemented method 300 returns to operation 310 where the planogram generating model 124 generates a new example planogram.

In operation 316, the planogram generating model 124 determines whether the imported planogram includes an additional fixture to be included in the generated planogram schematic. As discussed herein, the fixture data 116 includes a number of fixtures in the section of the imported planogram that is to be converted into the newly generated planogram. Where the planogram generating model 124 determines that the generated example planogram, generated in operation 310, is not the last fixture in the identified number of fixtures in the section, i.e., there is an additional fixture to be included in the planogram, the computer-implemented method 300 returns to operation 310 and generates an example planogram for the next fixture in the imported planogram. Where the planogram generating model 124 determines that the generated example planogram, generated in operation 310, is the last fixture in the identified number of fixtures in the section, i.e., there are no additional fixtures to be included in the planogram, the computer-implemented method 300 proceeds to operation 318.

In operation 318, the schematic generator 136 generates a schematic for a retail environment based on each generated planogram, for each associated fixture, in the imported planogram. For example, the schematic generator 136 generates an output of the form item, including fixture number, sequence number, orientation, capping/stacking units, and so forth, to build a schematic that can be used to apply the planogram to a physical retail environment. In some examples, the schematic further includes an illustration of the fixture(s) based on the retrieved fixture data and the items to be placed on the fixture(s) based on the generated planograms. Following the schematic being generated in operation 318, the computer-implemented method 300 terminates.

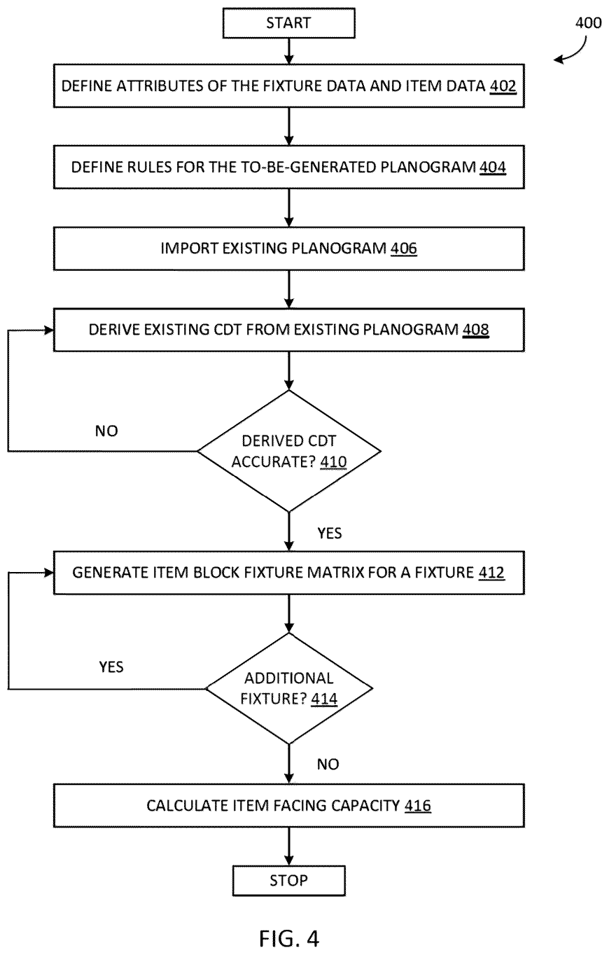

FIG. 4 illustrates an example computer-implemented method of reverse engineering existing merchandise rules according to an example. The computer-implemented method 400 is presented for illustration only and should not be construed as limiting. Other examples of the computer-implemented method 400 can be used without departing from the scope of the present disclosure. The computer-implemented method 400 can be implemented by one or more electronic devices described herein, such as the assortment creator 120 and the merchandise analyzer 122. In some examples, the computer-implemented method 400 is an example of operations 306 and 308 illustrated in FIG. 3.

The computer-implemented method 400 begins by the assortment creator 120 defining the attributes of the fixture data and item data in operation 402 and defining the rules for a yet-to-be-generated planogram in operation 404. For example, the assortment creator 120 defines the attributes and rules to be used to generate an updated planogram for a fixture or fixtures, including the item or items eligible to be included on the fixture, what items are mandatory for inclusion with other items, what items are exclusive relative to other items, and so forth. In some examples, operations 402 and 404 are performed in sequence, with operation 404 being performed after operation 402 or operation 402 being performed after operation 404. In other examples, operations 402 and 404 are performed simultaneously. As described herein, the fixture data includes at least one of a section name, a section length, a section least count, a jump or break sub-section in the section, a number of shelves in the section, shelf numbers, a depth of each shelf, a height of each shelf, an airgap by the shelf, and an overhang of the shelf. The item data includes at least one of item master data, item performance data at a store level, and item performance data at a cluster or chain level. Item master data includes an item code, item dimensions, item units per case, an item squish factor, whether the item is stackable, whether the item may be placed on a shelf cap and if so, how many may be placed on the cap, and item CDT data. The item performance data includes, at the store level, at least one of item unit sales per store per week, item dollar sales per store per week, and item profit per store week. The item performance data includes, at the chain or cluster level, at least one of item unit sales per store per week, item dollar sales per store per week, and item profit per store week.

In operation 406, the merchandise analyzer 122 imports, or identifies, the existing planogram. For example, the existing planogram may be stored in the data storage device 114 as an example of data 116, or may be received directly from an external device 138 in response to a request from the computing device 102 for the existing planogram.

In operation 408, the merchandise analyzer 122 derives an existing CDT from the imported existing planogram. As described herein, the derived CDT is a decision tree by which a consumer makes a purchasing decision to select a particular item or items instead of a potential replacement item. For example, the derived CDT includes assortment rules for why a consumer selects a particular shampoo of a particular size instead of a similar shampoo of the same size, a particular lotion of a particular size instead of a similar lotion, or any other suitable product. In some examples, items are arranged in blocks of items. For example, a block of items may include all shampoo items to be sold in the planogram, all sunscreen items to be sold in the planogram, and so forth. In another example, a block of shampoo items may be further subdivided into sub-blocks that each include a particular brand's shampoo items, while a block of sunscreen items may be further subdivide into sub-blocks that each include a particular brand's sunscreen items, and so forth. In combination with assortment rules for a planogram, such as having items, or blocks of items, sorted by volume on the fixture such that the volumes of the items descend in size from left to right on the fixture, having items, or blocks of items, sorted by volume on different fixtures such that the volumes of the items descend in size from a top fixture to a bottom fixture, sequencing rules for the order in which items, or blocks of items, are provided on the fixture, and so forth, the merchandise analyzer 122 derives the CDT for the particular imported planogram.

To derive the CDT from the existing imported planogram, as described herein, the merchandise analyzer 122 identifies a block on an existing shelf of the imported planogram, creates a block membership table form a highest CDT level to a lowest CDT level, executes block sequencing logic in order to determine the existing sequencing rules for the blocks, and identifies item capacity, pack-out, and days of supply by facings by each fixture according to the orientation of the items by stacking and capping the items.

In operation 410, the merchandise analyzer 122 determines whether the derived CDT for the imported planogram is accurate. In some examples, the merchandise analyzer 122 receives feedback via the user interface device 110 from a user of the computing device that indicates whether the derived CDT for the imported planogram is accurate. In other examples, CDT data is stored as data 116 in the data storage device 114 or at an external device, such as the server 140, and the merchandise analyzer 122 compares the derived CDT to the stored CDT data. Where the derived CDT is determined to not be accurate, or does not meet an accuracy threshold, the computer-implemented method 400 returns to operation 408 and the merchandise analyzer 122 performs additional analysis to update the derived CDT. In examples where the derived CDT is determined to be accurate, the computer-implemented method 400 proceeds to operation 412.

In operation 412, based on determining the derived CDT is accurate, the merchandise analyzer 122 generates an item-block-fixture matrix for a fixture. The item-block-fixture matrix identifies, for each item, which block the item is included in and which fixture, or shelf, the block is placed on. For example, a particular shampoo item that is identified as the third item in a second block on a fourth fixture may be identified within the item-block-fixture matrix as 3:2:4.

In operation 414, the merchandise analyzer 122 determines whether an additional fixture is present in the planogram. In examples where an additional fixture is present in the planogram, the computer-implemented method 400 returns to operation 412 and generates an item-block-fixture matrix for the next fixture. In examples where an additional fixture is not present in the planogram, the computer-implemented method 400 proceeds to operation 416.

In operation 416, the merchandise analyzer 122 calculates the item facing capacity for the fixtures. As described herein, the item facing capacity value is a value that represents the capacity of item facings for a particular fixture. As noted above, item data for each item includes facings data. The facings data includes a number of facings on an item, such as one, two, or four, and the length of each facing. Some items may be advantageously presented on a fixture with a front facing, which other items may be advantageously presented on the fixture with a side facing. In other examples, the facings data includes only a single facing, e.g., a front facing, with a length for the front facing. A stackable item capacity is determined based on multiplying a round down of the fixture and item height by the round down of the fixture and item width. Item capacity for a fixture to be generic is determined in a similar manner with the addition of adding a round down value of the fixture and item depth. Following the item facing capacity being calculated, the computer-implemented method 400 terminates.

FIG. 5 illustrates an example computer-implemented method of generating a recommendation of an example planogram according to an example. The computer-implemented method 500 is presented for illustration only and should not be construed as limiting. Other examples of the computer-implemented method 500 can be used without departing from the scope of the present disclosure. The computer-implemented method 500 can be implemented by one or more electronic devices described herein, such as the first model 126. In some examples, the computer-implemented method 500 is an example of operation 310 illustrated in FIG. 3.

The computer-implemented method 500 begins by the first model 126 identifying a fixture in operation 502. The fixture is identified in the imported planogram and derived CDT from the imported planogram. In some examples, the first identified fixture is a top fixture in the planogram. In some examples, the first identified feature is a bottom fixture in the planogram. In some examples, the first identified feature is a fixture that is determined to have the greatest priority in the planogram, such as a fixture that is anticipated to provide the greatest volume of sales or cost of sales.

In operation 504, the first model 126 identifies various data for each item available to be included in the to-be-generated planogram, including items that are included on the first fixture in the existing, imported planogram as well as items that are not included in the existing, imported planogram. For example, the first model 126 determines days of supply (DOS) data for each item and average rate of sale information for each item. The DoS data includes target DoS (TDoS) data, which is the target for days of supply for a particular item, and achieved DoS (ADOS) data, which is the days of supply that is actually achieved for the particular item. In some examples, the first model 126 further sorts the list of items by average rate of sale (ARS) from highest to lowest.

In operation 506, the first model 126 analyzes the TDOS and ADOS data for each item and, for each item with an excess DoS, i.e., where the ADOS is greater than the TDOS, reduces, the facing of the item. In other words, if the achieved days of supply is greater than the target days of supply for an item, meaning that an achieved supply of the item on the fixture is greater than a desired supply of the item, the number of facings of the items are reduced so that a lesser quantity of the item will be included in the to-be-generated planogram, because more of the items are included on the fixture than are needed to be sold. Reducing the facings enables additional items and/or a greater quantity of items having a greater TDOS to be placed on the fixture to increase sales. In some examples, following the facings of various items being shrunk, the first model 126 identifies the available free space on the fixture.

In operation 508, the first model 126 expands facings of items for which the ADOS is less than the TDoS. In other words, for items that have an achieved days of supply that is less than the target days of supply, meaning that the item is not sufficiently stocked and runs out prior to the target date of supply for the item, additional facings of the item are added so that the target days of supply may be achieved.

As described herein, in operation 504 the first model 126 generated a list of items available to be included in the planogram that is sorted by average rate of sale. In operation 510, the first model 126 determines whether to add new items, which are not presently on a fixture in the imported, existing planogram, to the fixture by determining, for each item, whether an average rate of sale of the new item is greater than an average rate of sale of an existing item that, of items on the fixture, has the lowest average rate of sale. For example, the first model 126 identifies the highest ranked item that is not presently included on the fixture and compares the average rate of sale of the item to the average rate of sale of the existing item having the lowest average rate of sale. Where the average rate of sale of the new item is greater than the average rate of sale of the existing item, the first model 126 adds the new item to the fixture in operation 512 per the eligibility derived by the merchandise analyzer 122. Where the average rate of sale of the new item is not greater than the average rate of sale of the existing item, the new item is not added to the fixture and the method proceeds to operation 516.

Following the addition of a new item to the fixture in operation 512, the first model 126 determine whether there is an additional item in the sorted list to be reviewed for potential inclusion in the planogram. For example, the first model 126 determines whether there is a next highest ranked item that is not presently included on the fixture. Where the answer is yes, the first model 126 returns to operation 510 to compare the average rate of sale of the item to the average rate of sale of the existing item having the lowest average rate of sale.

As the computer-implemented method 500 proceeds and the first model 126 compares items having continuously lower average rates of sale, the first model 126 eventually determines that an item has an average rate of sale that is equal to or less than that of the currently lowest ranked item on the fixture. At this time, the first model 126 determines the optimal selection of items is present on the fixture and proceeds to operation 516. In operation 516, the first model 126 determines whether the planogram includes an additional fixture. Where an additional fixture is present in the planogram, the computer-implemented method 500 returns to operation 502 and identifies the next fixture. In examples where the first model 126 determines there is not an additional fixture, the computer-implemented method 500 terminates.

It should be understood that although illustrated herein as a series of steps, various examples are possible. Various operations illustrated in FIG. 5 may be performed in a different order than as presented herein without departing from the scope of the present disclosure. For example, although FIG. 5 illustrates operation 508 as occurring prior to operations 510-514, in some examples operations 510-514 are performed prior to or concurrently with operation 508.

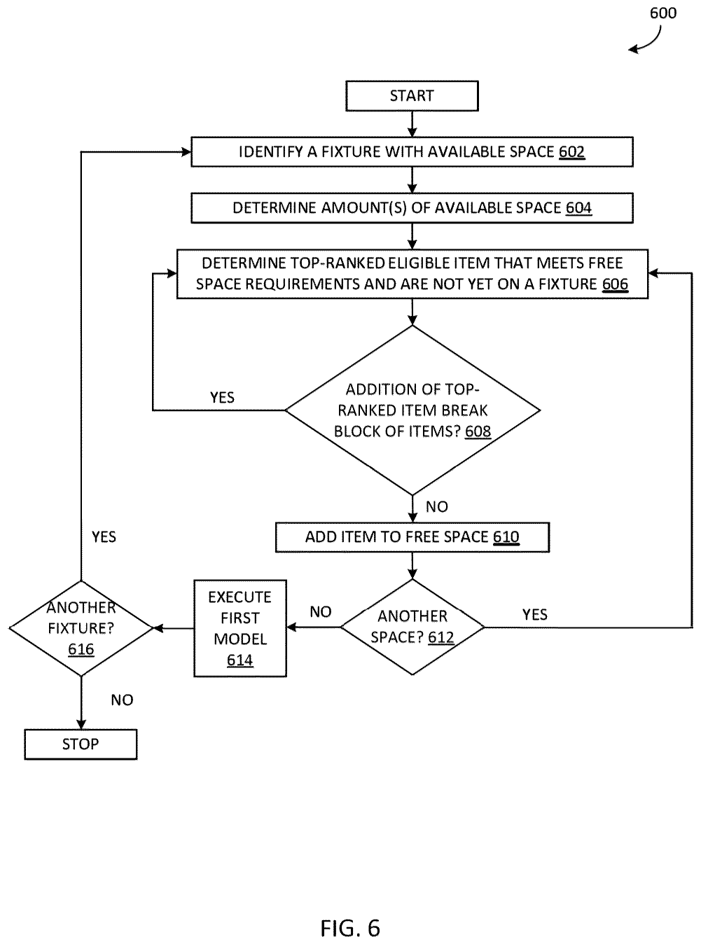

FIG. 6 illustrates an example computer-implemented method of generating a recommendation of an example planogram according to an example. The computer-implemented method 600 is presented for illustration only and should not be construed as limiting. Other examples of the computer-implemented method 600 can be used without departing from the scope of the present disclosure. The computer-implemented method 600 can be implemented by one or more electronic devices described herein, such as the first model 126 and the second model 128. In some examples, the computer-implemented method 600 is an example of operation 310 illustrated in FIG. 3.

The computer-implemented method 600 begins by the second model 128 identifying a fixture having available space in operation 602. The fixture is identified in the imported planogram and derived CDT from the imported planogram. In some examples, the first identified fixture is a top fixture in the planogram. In some examples, the first identified features is a bottom fixture in the planogram. In some examples, the first identified feature is a fixture that is determined to have a greatest priority in the planogram, such as a fixture that is anticipated to provide the greatest volume of sales or cost of sales. In operation 604, the second model 128 determines an amount of available space on the identified fixture. The available space may be quantified as a number of available item facings, a numerical amount of space specified in inches or centimeters, or any other suitable method.

In operation 606, the second model 128 determines a top-ranked eligible item that meets the free space requirements and is not yet on a fixture in the planogram. In some examples, the second model 128 determines a top-ranked eligible item based on the list of items sorted by average rate of sales as described herein. In other examples, the second model 128 utilizes a second list of items sorted by average rate of sales that includes items from lower ranked fixtures in the planogram, enabling some items to be transferred between fixtures.

In operation 608, the second model 128 determines whether the addition of the identified top-ranked item would break an existing block of items on the fixture. As described herein, items are arranged on a fixture in blocks of items. Blocking data includes rules determining a block sequence, block type, and block adjacencies for a particular block. The second model 128 analyzes the blocking rules for blocks on either side of an identified free space and determines whether the addition of the identified top-ranked item would violate any of the rules of the blocking data for each block. In examples where the addition of the identified top-ranked item would violate any one of the rules of the blocking data for each block, and therefore would break the existing block or blocks of item, the second model 128 determines not to add the top-ranked eligible item to the free space and returns to operation 606, in which the second model 128 determines a next-ranked eligible item to evaluate as a potential addition to the free space.

In examples where the addition of the identified top-ranked item would not violate any of the rules of the blocking data for each block, and therefore would not break the existing block or blocks of item, the second model 128 adds the top-ranked eligible item to the free space in operation 610. Following the item being added to the free space, the second model 128 determines whether there is another free space on the fixture to be analyzed in operation 612. Where there is another free space on the fixture to analyze, the second model 128 returns to operation 606. In examples where there are other free spaces on the fixture to analyze, the computer-implemented method 600 executes the first model 128, as illustrated in FIG. 5, to complete the items listed on the fixture. For example, the first model 128 shrinks the remaining facings to one, expands facings of items for which the ADOS is less than the TDOS, and adds new items for which the average rate of sale is greater than the average rate of sale of an existing item until all items having an average rate of sale on the fixture are greater than all items having an average rate of sale that are not on the fixture.

Following the execution of the first model 126, the second model 128 determines whether there is another fixture in the imported planogram to be evaluated in operation 616. In examples where there is another fixture to be evaluated, the computer-implemented method 600 returns to operation 602 and identifies the next fixture having available space. In examples where there is no other fixture to be evaluated, the computer-implemented method 600 terminates.

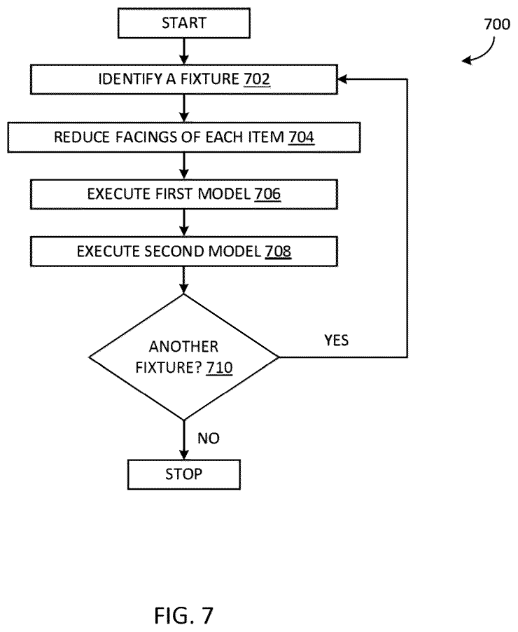

FIG. 7 illustrates an example computer-implemented method of generating a recommendation of an example planogram according to an example. The computer-implemented method 700 is presented for illustration only and should not be construed as limiting. Other examples of the computer-implemented method 700 can be used without departing from the scope of the present disclosure. The computer-implemented method 700 can be implemented by one or more electronic devices described herein, such as the first model 126, second model 128, and third model 130. In some examples, the computer-implemented method 700 is an example of operation 310 illustrated in FIG. 3.

The computer-implemented method 700 begins by the third model 130 identifying a fixture in operation 702. In some examples, a fixture is identified in the imported planogram and derived CDT from the imported planogram. In some examples, the first identified fixture is a top fixture in the planogram. In some examples, the first identified feature is a bottom fixture in the planogram. In some examples, the first identified feature is a fixture that is determined to have a greatest priority in the planogram, such as a fixture that is anticipated to provide the greatest volume of sales or cost of sales.

In operation 704, the third model 130 creates space on the fixture by reducing, or shrinking, the facings of various items on the fixture. The third model 130 determines the TDOS and ADOS of each item and reduces the facings of each item until the facings correspond to an ADOS value that is less than the TDOS of the respective item. For example, ADOS is calculated based on the width of the item, the depth of the fixture, and the average daily rate of unit sales of the item. First, the third model 130 calculates how many units will fit on the fixture for a single facing. This equals the depth of the fixture divided by the width of the item. The ADOS is equal to the number of units per facing divided by the average daily rate of unit sales. TDOS is determined by the frequency at which the fixture is replenished with items, such as manually restocked from a store backroom or warehouse. Thus, ADOS/TDOS dictates the number of facings. If ADOS/TDOS is greater than one, the number of facings can be reduced because more there are more facings than required to supply demand. However, if ADOS/TDos is less than one, facings may be added in order to ensure the inventory on the fixture is sufficient to support demand.

Once the additional space has been generated on the fixture, in operation 706 the first model 126 is executed as illustrated in FIG. 5 and as described herein. Accordingly, the first model 126 adds new items on to the fixture without changing the fixture upon which any item is placed and while maintaining compliance with the blocking rules for the items. In operation 708 the second model 128 is executed as illustrated in FIG. 6 and as described herein. Accordingly, the second model 128 creates space on the fixture where an eligible item may fit, including, in some instances, moving items between fixtures, while maintaining compliance with the blocking rules for the items.

In operation 710, the third model 130 determines whether the planogram includes an additional fixture. Where an additional fixture is present in the planogram, the computer-implemented method 700 returns to operation 702 and identifies the next fixture. In examples where the third model 130 determines there is no additional fixture, the computer-implemented method 700 terminates.

In various other examples, the fourth model 132 is implemented to generate the planogram. While each of the first model 126, the second model 128, and the third model 130 modify an existing and improve an existing planogram fixture by fixture, the fourth model 132 utilizes the derived CDT and determined block sequencing, removes all existing items from fixtures, and, based on the derived CDT, determines an optimal arrangement of items on the fixtures from the imported planogram without regard for the initial arrangement of the items. For example, the fourth model 132 imports an existing planogram, derives the CDT, arrangement of fixtures, and block sequencing rules from the planogram, generates a list of prioritized items based on the derived CDT, and generates a planogram based on the arrangement of fixtures, block sequencing rules, and list of prioritized items. For example, the fourth model 132 may use a linear program, a genetic algorithm, or any other suitable optimization algorithm with business rules coded in as constraints and the optimal solution will meet the objectives specified, such as monetary sales value or profit or volumes or a combination of multiple objectives.

It should be understood that the various models described herein may be used separately or in conjunction to generate a planogram for a retail environment. In various examples, one or more of the first model 126, second model 128, and third model 130 may be selected due to various desired parameters. For example, the first model 126 presents the most constrained option for item-fixture assignment, meaning that of the first model 126, second model 128, and third model 130, the first model 126 generates a resulting planogram that induces the least change from the imported planogram, while the third model 130 presents the least constrained option for item-fixture assignment and the second model 128 presents an intermediately-constrained option for item-fixture assignment that is less constrained than the first model 126 and more constrained than the third model 130. In various examples, the fourth model 132 is implemented with the ability to keep all or a part of the list of constraints.

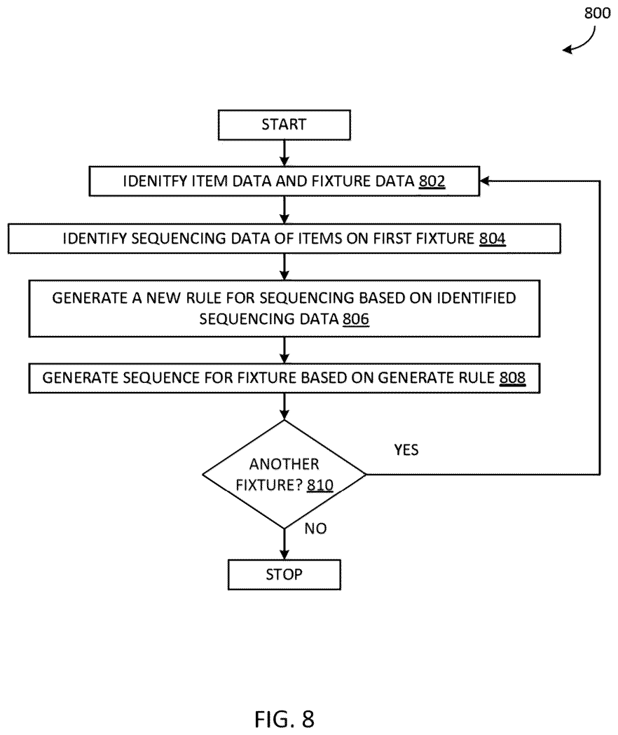

FIG. 8 illustrates an example computer-implemented method of generating a recommendation of an example planogram according to an example. The computer-implemented method 800 is presented for illustration only and should not be construed as limiting. Other examples of the computer-implemented method 800 can be used without departing from the scope of the present disclosure. The computer-implemented method 800 can be implemented by one or more electronic devices described herein, such as the schematic generator 136. In some examples, the computer-implemented method 800 is an example of operation 318 illustrated in FIG. 3.

The computer-implemented method 800 begins by the schematic generator 136 identifying item data and fixture date in operation 802. For example, where the computer-implemented method 800 is an example of operation 318, identifying the item data and fixture data includes pulling the fixture data acquired in operation 302 and the item data acquired in operation 304. As described herein, the fixture data includes at least one of a section name, a section length, a section least count, a jump or break sub-section in the section, a number of fixtures in the section, fixture, or shelf, numbers, a depth of each shelf, a height of each shelf, an airgap by the shelf, and an overhang of the shelf. The item data includes at least one of item master data, item performance data at a store level, and item performance data at a cluster or chain level. Item master data includes an item code, item dimensions, item units per case, an item squish factor, whether the item is stackable, whether the item may be placed on a shelf cap and if so, how many may be placed on the cap, and item CDT data. The item performance data includes, at the store level, at least one of item unit sales per store per week, item dollar sales per store per week, and item profit per store week. The item performance data includes, at the chain or cluster level, at least one of item unit sales per store per week, item dollar sales per store per week, and item profit per store week.

In operation 804, the schematic generator 136 identifies sequencing data of the items on the first fixture. As described herein, sequencing data includes an attribute used for sequencing and an attribute value flow for sequencing such as ascending, descending, or qualitative. For example, the identified item data for a first fixture indicates three items that, in order, are a sunscreen in a 40-ounce (oz) bottle with an SPF of 50, a sunscreen in a 32 oz bottle with an SPF of 50, and a sunscreen in a 20 oz bottle with an SPF of 50. The item data indicates bottles 32 oz and greater are identified as large. Thus, the sequencing data indicates “large 50”: “large 50”: “medium 50” for the three items. The first sequencing attribute is size and the second sequencing attribute is SPF value.

In operation 806, the schematic generator 136 generates a new rule for sequencing based on the identified sequencing data. For example, in the example above where the sequencing data indicates “large 50”: “large 50”: “medium 50” for the three items, the generated sequence rule may be that for items in the same category, e.g., sunscreen, having the same second sequencing attribute, the items are to be arranged from a greatest first sequencing attribute, e.g., size, to a least first sequencing attribute.

In operation 808, the schematic generator 136 generates a sequence for the items on the first fixture according to the generated rules for sequencing. For example, the schematic generator 136 identifies items included on the first fixture in the planogram generated in operation 310 and applies the generated rules for sequencing to the identified items in order to generate the sequence of items on the first fixture.

In operation 810, the schematic generator 136 determines whether the imported planogram includes an additional fixture for which a sequence of items is to be generated. Where an additional fixture is present in the planogram, the computer-implemented method 800 returns to operation 802 and identifies the next fixture. In examples where the schematic generator 136 determines there is not an additional fixture, the computer-implemented method 800 terminates.

### Example Operating Environment

FIG. 9 is a block diagram of an example computing device 900 for implementing aspects disclosed herein and is designated generally as computing device 900. Computing device 900 is an example of a suitable computing environment and is not intended to suggest any limitation as to the scope of use or functionality of the examples disclosed herein. Neither should computing device 900 be interpreted as having any dependency or requirement relating to any one or combination of components/modules illustrated. The examples disclosed herein may be described in the general context of computer code or machine-useable instructions, including computer-executable instructions such as program components, being executed by a computer or other machine, such as a personal data assistant or other handheld device. Generally, program components including routines, programs, objects, components, data structures, and the like, refer to code that performs particular tasks, or implement particular abstract data types. The disclosed examples may be practiced in a variety of system configurations, including personal computers, laptops, smart phones, mobile tablets, hand-held devices, consumer electronics, specialty computing devices, etc. The disclosed examples may also be practiced in distributed computing environments when tasks are performed by remote-processing devices that are linked through a communications network.

Computing device 900 includes a bus 920 that directly or indirectly couples the following devices: computer-storage memory 902, one or more processors 908, one or more presentation components 910, I/O ports 914, I/O components 916, a power supply 918, and a network component 912. While computing device 900 is depicted as a seemingly single device, multiple computing devices 900 may work together and share the depicted device resources. For example, memory 902 may be distributed across multiple devices, and processor(s) 908 may be housed with different devices.

Bus 920 represents what may be one or more busses (such as an address bus, data bus, or a combination thereof). Although the various blocks of FIG. 9 are shown with lines for the sake of clarity, delineating various components may be accomplished with alternative representations. For example, a presentation component such as a display device is an I/O component in some examples, and some examples of processors have their own memory. Distinction is not made between such categories as “workstation,” “server,” “laptop,” “hand-held device,” etc., as all are contemplated within the scope of FIG. 9 and the references herein to a “computing device.” Memory 902 may take the form of the computer-storage media references below and operatively provide storage of computer-readable instructions, data structures, program modules and other data for computing device 900. In some examples, memory 902 stores one or more of an operating system, a universal application platform, or other program modules and program data. Memory 902 is thus able to store and access data 904 and instructions 906 that are executable by processor 908 and configured to carry out the various operations disclosed herein.

In some examples, memory 902 includes computer-storage media in the form of volatile and/or nonvolatile memory, removable or non-removable memory, data disks in virtual environments, or a combination thereof. Memory 902 may include any quantity of memory associated with or accessible by computing device 900. Memory 902 may be internal to computing device 900 (as shown in FIG. 9), external to computing device 900, or both. Examples of memory 902 include, without limitation, random access memory (RAM); read only memory (ROM); electronically erasable programmable read only memory (EEPROM); flash memory or other memory technologies; CD-ROM, digital versatile disks (DVDs) or other optical or holographic media; magnetic cassettes, magnetic tape, magnetic disk storage or other magnetic storage devices; memory wired into an analog computing device; or any other medium for encoding desired information and for access by computing device 900. Additionally, or alternatively, memory 902 may be distributed across multiple computing devices 900, for example, in a virtualized environment in which instruction processing is carried out on multiple computing devices 900. For the purposes of this disclosure, “computer storage media,” “computer-storage memory,” “memory,” and “memory devices” are synonymous terms for computer-storage memory 902, and none of these terms include carrier waves or propagating signaling.

Processor(s) 908 may include any quantity of processing units that read data from various entities, such as memory 902 or I/O components 916 and may include CPUs and/or GPUs. Specifically, processor(s) 908 are programmed to execute computer-executable instructions for implementing aspects of the disclosure. The instructions may be performed by the processor, by multiple processors within computing device 900, or by a processor external to client computing device 900. In some examples, processor(s) 908 are programmed to execute instructions such as those illustrated in the in the accompanying drawings. Moreover, in some examples, processor(s) 908 represent an implementation of analog techniques to perform the operations described herein. For example, the operations may be performed by an analog client computing device 900 and/or a digital client computing device 900. Presentation component(s) 910 present data indications to a user or other device. Exemplary presentation components include a display device, speaker, printing component, vibrating component, etc. One skilled in the art will understand and appreciate that computer data may be presented in a number of ways, such as visually in a graphical user interface (GUI), audibly through speakers, wirelessly between computing devices 900, across a wired connection, or in other ways. I/O ports 914 allow computing device 900 to be logically coupled to other devices including I/O components 916, some of which may be built in. Example I/O components 916 include, for example but without limitation, a microphone, joystick, game pad, satellite dish, scanner, printer, wireless device, etc.

Computing device 900 may operate in a networked environment via network component 912 using logical connections to one or more remote computers. In some examples, network component 912 includes a network interface card and/or computer-executable instructions (e.g., a driver) for operating the network interface card. Communication between computing device 900 and other devices may occur using any protocol or mechanism over any wired or wireless connection. In some examples, network component 912 is operable to communicate data over public, private, or hybrid (public and private) using a transfer protocol, between devices wirelessly using short range communication technologies (e.g., near-field communication (NFC), Bluetooth™ branded communications, or the like), or a combination thereof. Network component 912 communicates over wireless communication link 922 and/or a wired communication link 922a to a cloud resource 924 across network 926. Various different examples of communication links 922 and 922a include a wireless connection, a wired connection, and/or a dedicated link, and in some examples, at least a portion is routed through the internet.

Although described in connection with an example computing device 900, examples of the disclosure are capable of implementation with numerous other general-purpose or special-purpose computing system environments, configurations, or devices. Examples of well-known computing systems, environments, and/or configurations that may be suitable for use with aspects of the disclosure include, but are not limited to, smart phones, mobile tablets, mobile computing devices, personal computers, server computers, hand-held or laptop devices, multiprocessor systems, gaming consoles, microprocessor-based systems, set top boxes, programmable consumer electronics, mobile telephones, mobile computing and/or communication devices in wearable or accessory form factors (e.g., watches, glasses, headsets, or earphones), network PCs, minicomputers, mainframe computers, distributed computing environments that include any of the above systems or devices, virtual reality (VR) devices, augmented reality (AR) devices, mixed reality devices, holographic device, and the like. Such systems or devices may accept input from the user in any way, including from input devices such as a keyboard or pointing device, via gesture input, proximity input (such as by hovering), and/or via voice input.

Examples of the disclosure may be described in the general context of computer-executable instructions, such as program modules, executed by one or more computers or other devices in software, firmware, hardware, or a combination thereof. The computer-executable instructions may be organized into one or more computer-executable components or modules. Generally, program modules include, but are not limited to, routines, programs, objects, components, and data structures that perform particular tasks or implement particular abstract data types. Aspects of the disclosure may be implemented with any number and organization of such components or modules. For example, aspects of the disclosure are not limited to the specific computer-executable instructions or the specific components or modules illustrated in the figures and described herein. Other examples of the disclosure may include different computer-executable instructions or components having more or less functionality than illustrated and described herein. In examples involving a general-purpose computer, aspects of the disclosure transform the general-purpose computer into a special-purpose computing device when configured to execute the instructions described herein.

By way of example and not limitation, computer readable media comprise computer storage media and communication media. Computer storage media include volatile and nonvolatile, removable and non-removable memory implemented in any method or technology for storage of information such as computer readable instructions, data structures, program modules, or the like. Computer storage media are tangible and mutually exclusive to communication media. Computer storage media are implemented in hardware and are non-transitory, i.e., exclude carrier waves and propagated signals. Computer storage media for purposes of this disclosure are not signals per se. Exemplary computer storage media include hard disks, flash drives, solid-state memory, phase change random-access memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that may be used to store information for access by a computing device. In contrast, communication media typically embody computer readable instructions, data structures, program modules, or the like in a modulated data signal such as a carrier wave or other transport mechanism and include any information delivery media.

In some examples, a computer-implemented method includes acquiring fixture data for a fixture; acquiring item data for a plurality of items to be displayed on fixture; importing an existing planogram, the imported existing planogram comprising an existing location of each item of the plurality of items on the fixture; based on identified assortment rules, generating an updated planogram for the fixture, the generated updated planogram for the fixture including an optimized placement of the plurality of items on the fixture; and generating a recommended schematic for a retail environment based on the generated updated planogram.

In some examples, a system includes a memory; and a processor coupled to the memory, a pre-processor, implemented on the processor, configured to acquire fixture data for a fixture, acquire item data for a plurality of items to be displayed on fixture, and import an existing planogram, the imported existing planogram comprising an existing location of each item of the plurality of items on the fixture; a planogram generator, implemented on the processor, configured to, based on identified assortment rules, generate an updated planogram for the fixture, the generated updated planogram for the fixture including an optimized placement of the plurality of items on the fixture; and a schematic generator, implemented on the processor, configured to generate a recommended schematic for a retail environment based on the generated updated planogram.

In some examples, one or more non-transitory computer-readable medium storing instructions that, when executed by a processor, cause the processor to acquire fixture data for a fixture, acquire item data for a plurality of items to be displayed on fixture, import an existing planogram, the imported existing planogram comprising an existing location of each item of the plurality of items on the fixture; derive an existing customer decision tree (CDT) from the imported planogram; identify the assortment rules based on the derived CDT; based on the identified assortment rules, generate an updated planogram for the fixture, the generated updated planogram for the fixture including an optimized placement of the plurality of items on the fixture; and generate a recommended schematic for a retail environment based on the generated updated planogram, the generated recommended schematic including a sequence of the plurality of items included in the generated updated planogram.

Further examples for are described herein.

Various examples further include one or more of the following:
determining, for a particular item, an achieved days of supply and a target days of supply;
adjusting a facing of the particular item of the plurality of items on the fixture according to the determined achieved days of supply and the determined target days of supply;
adding, to the fixture, a new item having an average rate of sale greater than an average rate of sale of an old item, of the plurality of items, having a lowest average rate of sale;
based on the achieved days of supply being greater than the target days of supply for the particular item, reducing the facing of the particular item on the fixture;
based on the achieved days of supply being less than the target days of supply for the particular item, expanding the facing of the particular item on the fixture;
determining an amount of available free space on the fixture;
determining a new item that takes up less space than the determined amount of available free space;
determining the determined new item does not break a block of items in the plurality of items on the fixture;
adding, to the fixture, the determined new item;
reducing a facing of each item on the fixture;
adding, to the fixture, a new item having an average rate of sale greater than an average rate of sale of an old item, of the plurality of items, having a lowest average rate of sale;
determining an amount of available free space on the fixture;
determining a new item that takes up less space than the determined amount of available free space;
determining the determined new item does not break a block of items in the plurality of items on the fixture;
adding, to the fixture, the determined new item;
identifying, in the existing planogram, an additional fixture;
generating a second updated planogram for the additional fixture;
identifying sequencing data of the plurality of items on the fixture;
generating a new sequencing rule for the fixture based on the identified sequencing data;
generating a sequence for the plurality of items included in the generated updated planogram;
deriving an existing customer decision tree (CDT) from the imported planogram; and
identifying the assortment rules based on the derived CDT.

The order of execution or performance of the operations in examples of the disclosure illustrated and described herein is not essential, and may be performed in different sequential manners in various examples. For example, it is contemplated that executing or performing a particular operation before, contemporaneously with, or after another operation is within the scope of aspects of the disclosure. When introducing elements of aspects of the disclosure or the examples thereof, the articles “a,” “an,” “the,” and “said” are intended to mean that there are one or more of the elements. The terms “comprising,” “including,” and “having” are intended to be inclusive and mean that there may be additional elements other than the listed elements. The term “exemplary” is intended to mean “an example of.” The phrase “one or more of the following: A, B, and C” means “at least one of A and/or at least one of B and/or at least one of C.”

Having described aspects of the disclosure in detail, it will be apparent that modifications and variations are possible without departing from the scope of aspects of the disclosure as defined in the appended claims. As various changes could be made in the above constructions, products, and methods without departing from the scope of aspects of the disclosure, it is intended that all matter contained in the above description and shown in the accompanying drawings shall be interpreted as illustrative and not in a limiting sense.

What is claimed is:

1. A computer-implemented method, comprising:
acquiring fixture data for a fixture;
acquiring item data for a plurality of items to be displayed on fixture;
importing an existing planogram, the imported existing planogram comprising an existing location of each item of the plurality of items on the fixture;
based on identified assortment rules, generating an updated planogram for the fixture, the generated updated planogram for the fixture including an optimized placement of the plurality of items on the fixture; and
generating a recommended schematic for a retail environment based on the generated updated planogram.

2. The computer-implemented method of claim 1, wherein generating the updated planogram for the fixture further comprises:
determining, for a particular item, an achieved days of supply and a target days of supply;
adjusting a facing of the particular item of the plurality of items on the fixture according to the determined achieved days of supply and the determined target days of supply; and
adding, to the fixture, a new item having an average rate of sale greater than an average rate of sale of an old item, of the plurality of items, having a lowest average rate of sale.

3. The computer-implemented method of claim 2, wherein adjusting the facing of each particular item of the plurality of items on the fixture further comprises:
based on the achieved days of supply being greater than the target days of supply for the particular item, reducing the facing of the particular item on the fixture; and
based on the achieved days of supply being less than the target days of supply for the particular item, expanding the facing of the particular item on the fixture.

4. The computer-implemented method of claim 1, wherein generating the updated planogram for the fixture further comprises:
determining an amount of available free space on the fixture;
determining a new item that takes up less space than the determined amount of available free space;
determining the determined new item does not break a block of items in the plurality of items on the fixture; and
adding, to the fixture, the determined new item.

5. The computer-implemented method of claim 1, wherein generating the updated planogram for the fixture further comprises:
reducing a facing of each item on the fixture;
adding, to the fixture, a new item having an average rate of sale greater than an average rate of sale of an old item, of the plurality of items, having a lowest average rate of sale;
determining an amount of available free space on the fixture;
determining a new item that takes up less space than the determined amount of available free space;
determining the determined new item does not break a block of items in the plurality of items on the fixture; and
adding, to the fixture, the determined new item.

6. The computer-implemented method of claim 1, further comprising:
identifying, in the existing planogram, an additional fixture; and
generating a second updated planogram for the additional fixture.

7. The computer-implemented method of claim 1, wherein generating a recommended schematic further comprises:
identifying sequencing data of the plurality of items on the fixture;
generating a new sequencing rule for the fixture based on the identified sequencing data; and
generating a sequence for the plurality of items included in the generated updated planogram.

8. The computer-implemented method of claim 1, wherein generating a recommended schematic further comprises:
deriving an existing customer decision tree (CDT) from the imported planogram; and
identifying the assortment rules based on the derived CDT.

9. A system, comprising:
a memory;
a processor coupled to the memory;
a pre-processor, implemented on the processor, configured to:
acquire fixture data for a fixture,
acquire item data for a plurality of items to be displayed on fixture, and
import an existing planogram, the imported existing planogram comprising an existing location of each item of the plurality of items on the fixture;
a planogram generator, implemented on the processor, configured to, based on identified assortment rules, generate an updated planogram for the fixture, the generated updated planogram for the fixture including an optimized placement of the plurality of items on the fixture; and
a schematic generator, implemented on the processor, configured to generate a recommended schematic for a retail environment based on the generated updated planogram.

10. The system of claim 9, wherein, to generate the updated planogram for the fixture, the planogram generator is further configured to:
determine, for a particular item, an achieved days of supply and a target days of supply;
adjust a facing of the particular item of the plurality of items on the fixture according to the determined achieved days of supply and the determined target days of supply; and
add, to the fixture, a new item having an average rate of sale greater than an average rate of sale of an old item, of the plurality of items, having a lowest average rate of sale.

11. The system of claim 10, wherein, to adjust the facing of each particular item of the plurality of items on the fixture, the planogram generator is further configured to:
based on the achieved days of supply being greater than the target days of supply for the particular item, reduce the facing of the particular item on the fixture; and
based on the achieved days of supply being less than the target days of supply for the particular item, expand the facing of the particular item on the fixture.

12. The system of claim 9, wherein, to generate the updated planogram for the fixture, the planogram generator is further configured to:
determine an amount of available free space on the fixture;
determine a new item that takes up less space than the determined amount of available free space;
determine the determined new item does not break a block of items in the plurality of items on the fixture; and
add, to the fixture, the determined new item.

13. The system of claim 9, wherein, to generate the updated planogram for the fixture, the planogram generator is further configured to:
reduce a facing of each item on the fixture;
add, to the fixture, a new item having an average rate of sale greater than an average rate of sale of an old item, of the plurality of items, having a lowest average rate of sale;
determine an amount of available free space on the fixture;
determine a new item that takes up less space than the determined amount of available free space;
determine the determined new item does not break a block of items in the plurality of items on the fixture; and
add, to the fixture, the determined new item.

14. The system of claim 9, wherein, to generate the recommended schematic, the schematic generator is further configured to:
identify sequencing data of the plurality of items on the fixture;
generate a new sequencing rule for the fixture based on the identified sequencing data; and
generate a sequence for the plurality of items included in the generated updated planogram.

15. One or more non-transitory computer-readable medium storing instructions that, when executed by a processor, cause the processor to:
acquire fixture data for a fixture,
acquire item data for a plurality of items to be displayed on fixture,
import an existing planogram, the imported existing planogram comprising an existing location of each item of the plurality of items on the fixture;
derive an existing customer decision tree (CDT) from the imported planogram;
identify the assortment rules based on the derived CDT;
based on the identified assortment rules, generate an updated planogram for the fixture, the generated updated planogram for the fixture including an optimized placement of the plurality of items on the fixture; and
generate a recommended schematic for a retail environment based on the generated updated planogram, the generated recommended schematic including a sequence of the plurality of items included in the generated updated planogram.

16. The one or more non-transitory computer-readable medium of claim 15, further storing instructions for generating the updated planogram for the fixture that, when executed by the processor, cause the processor to:
determine, for a particular item, an achieved days of supply and a target days of supply;
adjust a facing of the particular item of the plurality of items on the fixture according to the determined achieved days of supply and the determined target days of supply; and
add, to the fixture, a new item having an average rate of sale greater than an average rate of sale of an old item, of the plurality of items, having a lowest average rate of sale.

17. The one or more non-transitory computer-readable medium of claim 16, further storing instructions for adjusting the facing of each particular item of the plurality of items on the fixture that, when executed by the processor, cause the processor to:
based on the achieved days of supply being greater than the target days of supply for the particular item, reduce the facing of the particular item on the fixture; and
based on the achieved days of supply being less than the target days of supply for the particular item, expand the facing of the particular item on the fixture.

18. The one or more non-transitory computer-readable medium of claim 15, further storing instructions for generating the updated planogram for the fixture that, when executed by the processor, cause the processor to:
determine an amount of available free space on the fixture;
determine a new item that takes up less space than the determined amount of available free space;
determine the determined new item does not break a block of items in the plurality of items on the fixture; and
add, to the fixture, the determined new item.

19. The one or more non-transitory computer-readable medium of claim 15, further storing instructions for generating the updated planogram for the fixture that, when executed by the processor, cause the processor to:
reduce a facing of each item on the fixture;
add, to the fixture, a new item having an average rate of sale greater than an average rate of sale of an old item, of the plurality of items, having a lowest average rate of sale;
determine an amount of available free space on the fixture;
determine a new item that takes up less space than the determined amount of available free space;
determine the determined new item does not break a block of items in the plurality of items on the fixture; and
add, to the fixture, the determined new item.

20. The one or more non-transitory computer-readable medium of claim 15, further storing instructions for generating the recommended schematic that, when executed by the processor, cause the processor to:
identify sequencing data of the plurality of items on the fixture;
generate a new sequencing rule for the fixture based on the identified sequencing data; and
generate the sequence for the plurality of items included in the generated updated planogram.
